(19) United States
(12) Patent Application Publication
(10) Pub. No.: US 2009/0321861 A1
(43) Pub. Date: Dec. 31, 2009

(54) MICROELECTRONIC IMAGERS WITH STACKED LENS ASSEMBLIES AND PROCESSES FOR WAFER-LEVEL PACKAGING OF MICROELECTRONIC IMAGERS

(75) Inventors: Steven D. Oliver, San Jose, CA (US); Rick C. Lake, Meridian, ID (US); Ulrich C. Boettiger, Boise, ID (US)

Correspondence Address: Kramer Levin Naftalis & Frankel LLP, 1177 Avenue of the Americas, New York, NY, 10036, US

(73) Assignee: MICRON TECHNOLOGY, INC., Boise, ID (US)

(21) Appl. No.: 12/147,421

(22) Filed: Jun. 26, 2008

(51) Int. Cl. H01L 31/0232; H01L 31/18

(52) U.S. Cl. 257/432; 438/65; 257/E31.127

(57) ABSTRACT

Microelectronic imagers including stacked lens assemblies and process for wafer-level packaging of microelectronic imagers. One embodiment of a method for manufacturing stacked lens assemblies for integrated imagers comprises attaching a first lens substrate to a base spacer, fixing an intermediate spacer to the first lens substrate, and mounting a second lens substrate to the intermediate spacer. In a specific embodiment, the first lens substrate can be a component of a first lens unit and the second lens substrate can be a component of a second lens unit. Additionally, the first and second lens substrates can have one or more lens elements, aperture layers and/or filters on the substrates as described above or in other combinations.

### TECHNICAL FIELD

The following disclosure relates generally to microelectronic imagers including stacked lens assemblies and methods for manufacturing stacked lens assemblies and packaging microelectronic imagers. Several embodiments are directed toward wafer-level manufacturing of stacked lens assemblies and packaging stacked lens assemblies including microelectronic imagers.

### BACKGROUND

Microelectronic imagers are used in digital cameras, wireless devices with picture capabilities, products with IR or UV sensors, and many other applications. Cell phones and Personal Digital Assistants (PDAs), for example, often have microelectronic imagers for capturing and sending pictures. The growth rate of microelectronic imagers has been steadily increasing as they become smaller and produce better images with higher pixel counts.

Microelectronic imagers include image sensors that use Charged Coupled Device (CCD) systems, Complementary Metal-Oxide Semiconductor (CMOS) systems, or other systems. CCD image sensors have been widely used in digital cameras and other applications. CMOS image sensors are also very popular because they have low production costs, high yields, and small sizes. CMOS image sensors can provide these advantages because they are manufactured using technology and equipment developed for fabricating semiconductor devices. CMOS image sensors, as well as CCD image sensors, are accordingly “packaged” to protect the delicate components and to provide external electrical contacts.

Microelectronic imagers generally include an imager die with an image sensor, an interposer substrate or other lead system attached to one side of the die, and an optics unit at the other side of the die. Each optics unit is often a lens stack with a plurality of lenses, filters, and covers. The lens stacks are generally formed individually as separate, discrete optics units, and then each individual optics unit is attached to an individual image sensor die.

One concern of such packaging and manufacturing processes for stacked lens assemblies is that they are tedious and relatively expensive. For example, it is relatively expensive to build discrete lens stacks, accurately attach each individual lens stack to an image sensor die, and then encapsulate or otherwise protect the dies and the lens stacks. U.S. Patent Publication No. 2005/0275750, which is owned by Micron Technology, Inc. and incorporated herein by reference, discloses several embodiments for wafer-level fabrication of lenses and wafer-level packaging of microelectronic imagers to overcome these shortcomings. The apparatus and methods disclosed in U.S. Patent Publication 2005/0275750 provide a significant improvement in the efficiency, reliability and precision of packaging microelectronic imagers.

### BRIEF DESCRIPTION OF THE DRAWINGS

FIG. 1 is a schematic, cross-sectional view of an embodiment of a packaged microelectronic imager device.

FIGS. 2A-2E are schematic, cross-sectional views illustrating stages of an embodiment of a method for wafer-level manufacturing of a portion of a stacked lens assembly.

FIGS. 3A-3F are schematic, cross-sectional views illustrating stages of a process for wafer-level manufacturing of another portion of a stacked lens assembly.

FIG. 4 is a schematic, cross-sectional view of an embodiment of a wafer-level stacked lens assembly.

FIGS. 5A-5E are schematic, cross-sectional views of an embodiment of a process for assembling wafer-level stacked lens assemblies with wafer-level imager dies.

FIGS. 6A-6F are schematic, cross-sectional views of another embodiment of a process for wafer-level fabrication of a stacked lens assembly.

FIG. 7 is a schematic view of a system incorporating an embodiment of a microelectronic imager.

### DETAILED DESCRIPTION

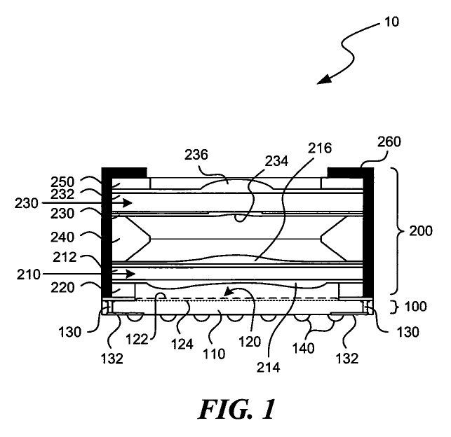

Specific details of several embodiments of the disclosure are described below with reference to packaged microelectronic imagers and methods for wafer-level packaging of microelectronic imagers. The microelectronic imagers are manufactured on semiconductor wafers with other substrates upon which and/or in which microelectronic devices, micromechanical devices, data storage elements, optics, read/write components, and other features are fabricated. Although many of the embodiments are described below with respect to CMOS imagers that have integrated circuits, other types of devices manufactured on other types of substrates can be fabricated using the following processes. Moreover, several other embodiments can have different configurations, components, or procedures than those described in this section. A person of ordinary skill in the art, therefore, will accordingly understand that other embodiments with additional elements, or without several of the features shown and described below with reference to FIGS. 1-7, are within the scope of the following disclosure.

FIG. 1 is a side cross-sectional view schematically illustrating an embodiment of a microelectronic imager 10 having an imager die 100 and a stacked lens assembly 200 attached to the imager die 100. In this embodiment, the imager die 100 includes a substrate 110, an image sensor 120 formed on and/or in the substrate 110, and interconnects 130 electrically coupled to the image sensor 120. The substrate 110 can be a semiconductor wafer formed from silicon or other semiconductor materials. The image sensor 120 can be a CMOS image sensor, a CCD image sensor, or another type of image sensor for capturing pictures. In some embodiments, the image sensor 120 can be another type of sensor for detecting radiation in non-visible spectrums (e.g., IR or UV ranges). The image sensor 120 is typically located at the front side of the substrate 110, and the embodiment of the image sensor 120 illustrated in FIG. 1 includes a plurality of microlenses 122 and integrated circuitry 124. The interconnects 130 can be through substrate interconnects that extend from the front side to the backside of the substrate 110. The interconnects 130 are electrically coupled to the integrated circuitry 124 and a redistribution structure 132 that has an array of contact pads at the backside of the substrate 110. The contact pads can be arranged to be within the footprint of each imager die 100, and the contact pads of the redistribution structure 132 can be configured to receive external connectors 140 (e.g., solder balls, solder paste, etc.). The imager die 100 and the interconnects 130 can be formed at the wafer level as described in U.S. Patent Publication No. 2005/0275750, or by other suitable processes known in the art.

The embodiment of the stacked lens assembly 200 illustrated in FIG. 1 includes a first lens unit 210, a base spacer 220 between the first lens unit 210 and the substrate 110 of the imager die 100, a second lens unit 230, and an intermediate spacer 240 between the first lens unit 210 and the second lens unit 230. The stacked lens assembly 200 can further include an optional top spacer 250 attached to the second lens unit 230 and an encapsulant 260 around the sides of the stacked lens assembly 200. The encapsulant 260 can also extend over a portion of the top spacer 250. The first lens unit 210, base spacer 220, second lens unit 230, intermediate spacer 240, and top spacer 250 can be formed from silica glass or other suitable materials that have approximately the same coefficients of thermal expansion. In a specific example, the lens units 210, 230 and spacers 220, 240 and 250 comprise quartz substrates that have a common coefficient of thermal expansion at least approximately the same as the substrate 110 of the imager die.

In one embodiment, the first lens unit 210 can include a first substrate 212, a first lens element 214, and a second lens element 216. The first and second lens elements 214 and 216 can be formed on or otherwise attached to the first substrate 212. The second lens unit 230 can similarly include a second substrate 232, a first lens element 234, and a second lens element 236 attached to or otherwise formed on the second substrate 232. The first and second substrates 212 and 232 can comprise glass, and the lens elements 214, 216, 234 and 236 can comprise a polymer or other transmissive material (e.g., glass). As explained in more detail below, the first lens elements 214, 234 and the second lens elements 216, 236 can be polymeric materials that are formed as either positive or negative lenses using imprint lithography, photolithography (pattern/etch), or a combination of imprint lithography and photolithography. Each of the lens elements 214, 216, 234 and 236 can be different from each other, or in other embodiments one or more of the lens elements can have common optical properties.

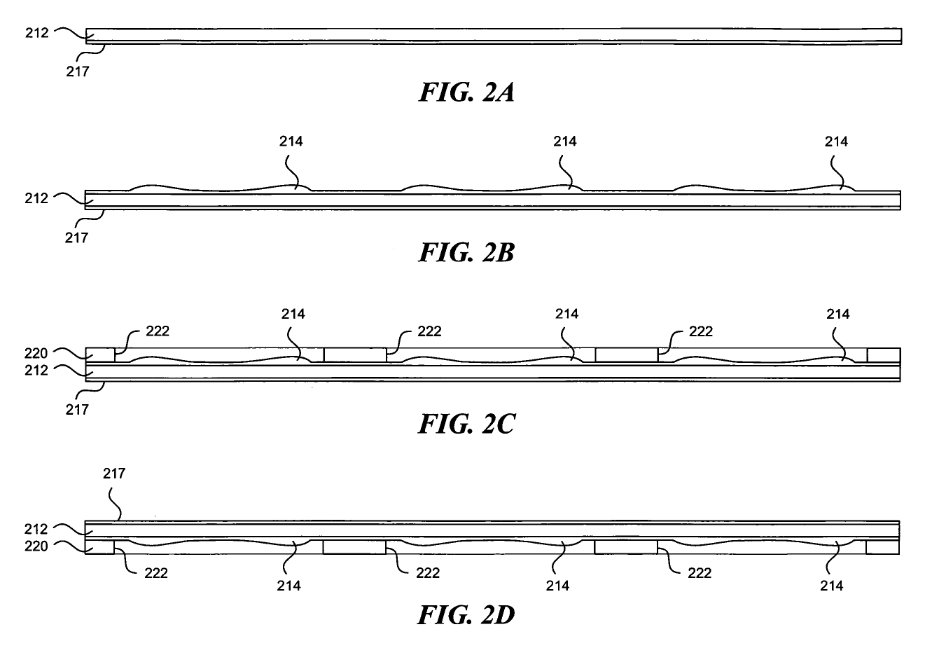

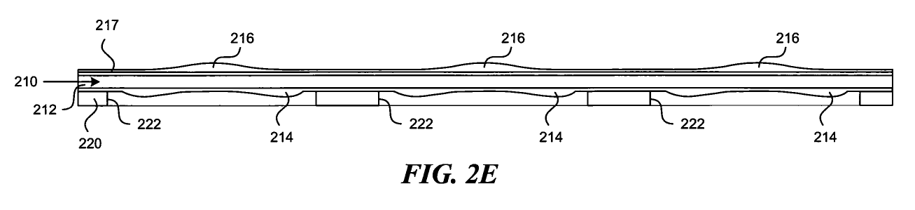

FIGS. 2A-2E are cross-sectional views that schematically illustrate stages of forming an embodiment of the first lens unit 210 and the base spacer 220. FIG. 2A illustrates an early stage in which the substrate 212 is a wafer. For example, the substrate 212 can initially be a wafer with a diameter of 200-300 mm. The substrate 212 can comprise glass or other materials that are suitably transmissive to the radiation that activates the image sensor. In a specific embodiment, the substrate 212 is a quartz wafer. The substrate 212 can be another material that, in many instances, has a coefficient of thermal expansion that is at least approximately equal to the coefficient of thermal expansion of an image sensor wafer made from silicon or another semiconductive material. The substrate 212 can optionally be covered with a coating 217 that filters, polarizes, or otherwise conditions the radiation. For example, the coating 17 can be an IR filter on one side of the substrate 212. The coating 217 can be deposited using a vapor deposition technique or other suitable deposition process known in the art.

FIG. 2B illustrates a subsequent stage in which a plurality of first lens elements 214 are formed on or otherwise attached to one side of the substrate 212. The first lens elements 214 can be formed using nano-imprint lithography with UV curable polymers, photolithography using etching of silica glass or a polymeric material, glass molding, hot-embossing, and other techniques known in the art. For example, the first lens elements 214 can be formed by depositing a polymeric coating onto a side of the substrate 212 and stamping or processing a master with multiple lens replications in a lens pattern into the coating before it has cured. In one embodiment, the polymeric material is cured before removing or releasing the stamp or master from the polymeric material. In a different embodiment, the stamp or master is released from the polymeric material before curing, and then the polymeric material is cured. The master forms a plurality of individual first lens elements 214 in a lens pattern, and the polymeric material has suitable optic properties for the radiation sensed by the image sensors. The second lens elements 216 can be formed using a similar process. Although the illustrated embodiment of the first lens unit 210 has first and second lends elements 214 and 216, other embodiments can have only one of the lens elements 214 or 216.

FIG. 2C illustrates a subsequent stage in which the base spacer 220 has been formed and attached to the side of the substrate 212 having the first lens elements 214. The base spacer 220 can also be a wafer having a form factor corresponding to the form factor of the substrate 212. The base spacer 220 can be formed from a wafer of the same material as the substrate 212, and thus the base spacer 220 can be a glass wafer or a wafer made from another material having a suitable coefficient of thermal expansion. The base spacer 220 can, for example, be a quartz wafer or a silica glass wafer. The base spacer 220 includes a plurality of apertures 222 arranged in the lens pattern and aligned with corresponding first lens elements 214 when the base spacer 220 is superimposed with the substrate 212. The apertures 222 can be formed by etching, cutting, molding, or other wafer manufacturing techniques. The base spacer 220 can be adhered to the substrate 212 using a suitable adhesive, or the polymeric material of the first lens elements 214 can be selected from an adhesive polymeric material that can adhere to the base spacer 220 in a b-stage cure. The material of the first lens elements 214 can accordingly be cured at the stage illustrated in FIG. 2B or at the stage illustrated in FIG. 2C depending upon whether the material of the first lens elements 214 also adheres the base spacer 220 to the first substrate 212.

FIG. 2D illustrates a subsequent stage in which the assembly illustrated in FIG. 2C is inverted so that the coating 217 faces upward, and FIG. 2E illustrates a subsequent stage in which a plurality of the second lens elements 216 are formed on the coating 217. The second lens elements 216 can be formed by depositing a suitable material onto the coating 217 and using any of the foregoing techniques to form the curvatures of the second lens elements. In other embodiments, the first lens elements 214 and/or the second lens elements 216 can be formed separately apart from the substrate 212 and then adhered to the substrate 212.

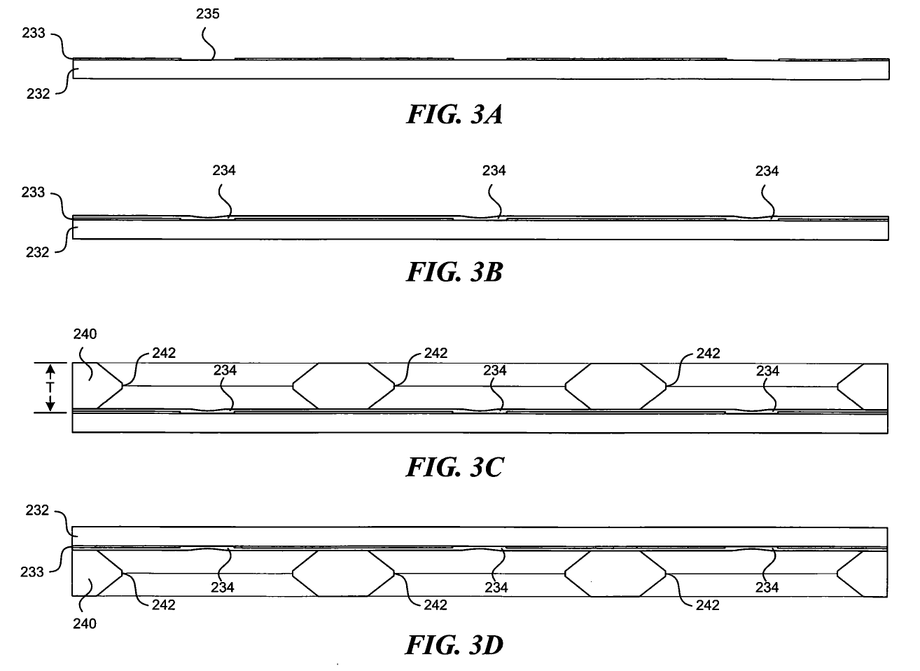

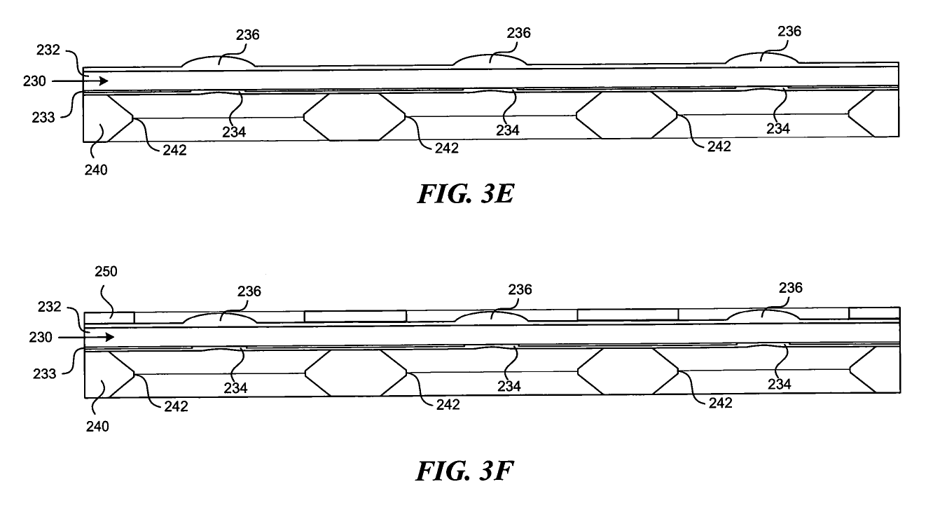

FIGS. 3A-3F are cross-sectional views schematically illustrating a number of stages of forming the second lens unit 230, the intermediate spacer 240, and the top spacer 250. FIG. 3A shows an early stage in which the second substrate 232 of the second lens unit 230 has a patterned aperture layer 233 with a plurality of apertures 235 corresponding to the lens pattern of the first and second lens elements 214 and 216 of the first lens unit 210 illustrated in FIG. 2E. The aperture layer 233, for example, can comprise chromium that is patterned and etched to form the apertures 235. The second substrate 232 can also be a wafer having a form factor corresponding to the first substrate 212. The second substrate 232 can be quartz, silica glass, or another suitable material having (a) a coefficient of thermal expansion at least approximately equal to the coefficient of thermal expansion of the first substrate 212 and (b) desirable transmission properties for the radiation sensed by the image sensors.

FIG. 3B illustrates a subsequent stage in which a plurality of first lens elements 234 are formed on the second substrate 232. The first lens elements 234 can be formed by depositing a polymeric material or another suitable material onto the side of the second substrate 232 having the aperture layer 233. The first lens elements 234 can be formed at the apertures 235 from a polymeric material using the same techniques described above with respect to the first lens unit 210.

FIG. 3C shows a subsequent stage in which the intermediate spacer 240 is bonded to the side of the second substrate 232 with the first lens elements 234. The intermediate spacer 240 can be formed from a material having a suitable coefficient of thermal expansion. The intermediate spacer 240, for example, can be formed from a suitable glass or another material having a coefficient of thermal expansion that is at least approximately equal to the coefficients of thermal expansion of the first substrate 212, the base spacer 220, and the second substrate 232. The intermediate spacer 240 can also be a wafer having a form factor corresponding to the form factor of the wafers of the first substrate 212, the base spacer 220, and the second substrate 232. The intermediate spacer 240 also has a thickness T that spaces the first substrate 212 apart from the second substrate 232 by a desired distance so that the lens elements on the first and second substrates 212 and 232 accurately focus and condition the radiation at the image sensor.

FIG. 3D shows a subsequent stage in which the second substrate 232 and the intermediate spacer 240 have been inverted, and FIG. 3E illustrates a stage in which a plurality of second lens elements 236 are formed on the other side of the second substrate 232. The second lens elements 236 can be formed using any of the techniques described above.

FIG. 3F shows a stage in which the top spacer 250 is bonded to the second substrate 232. The top spacer 250 can be a wafer having the form factor of the second substrate 232, and the top spacer 250 can have a plurality of openings 252 arranged in the lens pattern corresponding to the second lens elements 236. The openings 252 can be formed using etching, molding, cutting, or other wafer manufacturing techniques. The top spacer 250 can be formed from a material having a coefficient of thermal expansion that is at least substantially the same as that of the second substrate 232, the intermediate spacer 240, the first substrate 212, and/or the base spacer 220.

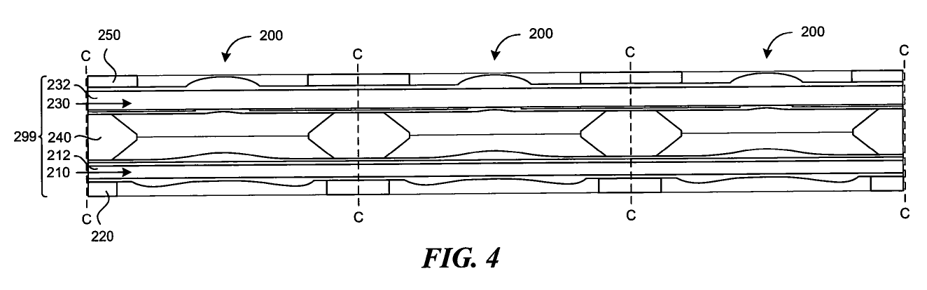

FIG. 4 is a side cross-sectional view schematically illustrating a wafer-level stacked lens assembly 299. In this embodiment, a first subassembly including the first lens unit 210 and the base spacer 220 is attached to a second subassembly including the intermediate spacer 240, the second lens unit 230, and the top spacer 250 to form the wafer-level lens assembly 299. The wafer-level stacked lens assembly 299 accordingly has a plurality of individual stacked lens assemblies 200.

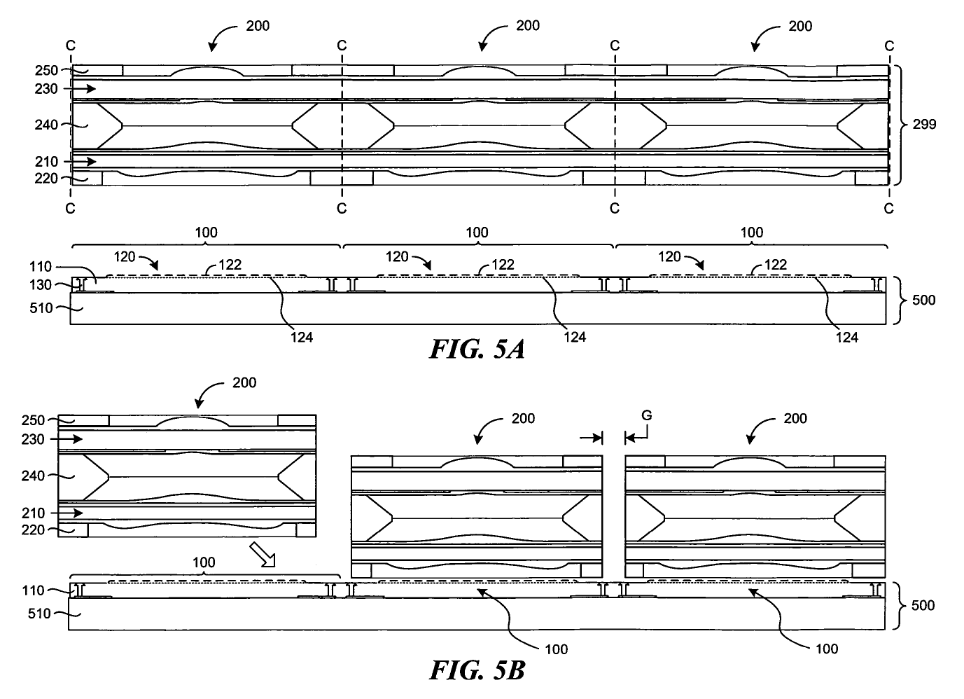

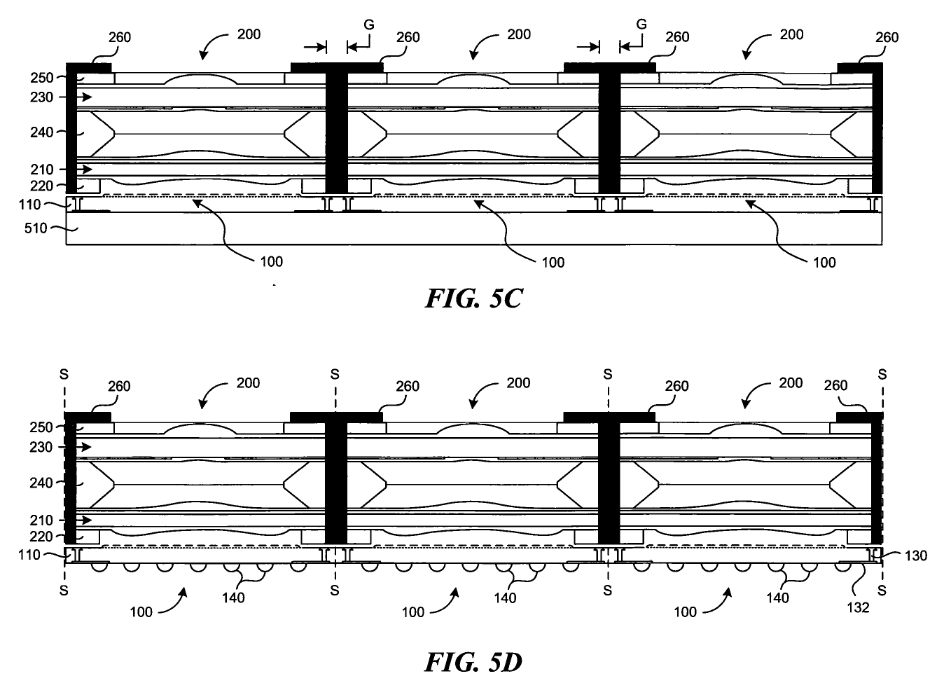

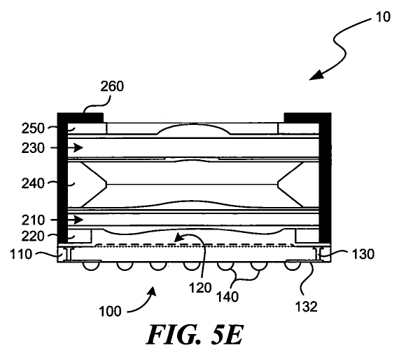

FIGS. 5A-5E illustrate stages of an embodiment of a method of assembling stacked lens assemblies with imager dies to form individual microelectronic imagers. FIG. 5A illustrates an early stage that includes providing an embodiment of the wafer-level stacked lens assembly 299 and an embodiment of a wafer-level imager die assembly 500. The wafer-level stacked lens assembly 299 includes a plurality of the stacked lens assemblies 200 as described above with reference to FIG. 4, and the wafer-level imager die assembly 500 includes a wafer of the semiconductor substrate 110 having a plurality of imager dies 100 and a wafer carrier 510. The wafer carrier 510 can be a tape, ceramic or other material suitable for supporting the substrate 110. At this stage of the process, both the wafer-level stacked lens assembly 299 and the semiconductor substrate 110 have the form factors of a wafer. The wafer-level stacked lens assembly 299 is then cut along lines C-C to separate individual stacked lens assemblies 200 from each other.

FIG. 5B illustrates a subsequent stage in which the individual stacked lens assemblies 200 are mounted to corresponding imager dies 100 on the substrate 110. The individual stacked lens assemblies 200 can be mounted to the substrate 110 using pick-and-place technology known in the art or other suitable techniques. In one embodiment, the imager dies 100 and the stacked lens assemblies 200 are tested so that only known good lens assemblies are mounted to known good dies. In an additional embodiment, faulty lens assemblies can be mounted to faulty dies to maintain the wafer-level form factor of imager dies and lens assemblies for subsequent processes. The individual stacked lens assemblies 200 are mounted to corresponding imager dies 100 on the substrate 110 such that the individual stacked lens assemblies 200 are spaced apart from each other by a gap G.

FIG. 5C illustrates a subsequent stage in which an encapsulant 260 is disposed in the gaps G between the individual stacked lens assemblies 200. The encapsulant 260 can be an epoxy or other type of protective material, and the encapsulant 260 can be opaque to the radiation. In several embodiments, the encapsulant 260 is also disposed over a perimeter portion of the top spacer 250 of the stacked lens assemblies 200 to define openings that control the amount of radiation that passes through the first and second lens units 210 and 230. The encapsulant 260 can be molded or otherwise deposited onto the wafer-level imager die assembly 500.

FIG. 5D illustrates a subsequent stage in which the wafer carrier 510 is removed from the semiconductor substrate 110 and the electrical connectors 140 are attached to or otherwise deposited onto the contact pads of the redistribution structure 132 at the back side of the substrate 110. At this stage, the substrate 110, the stacked die assemblies 200, and the encapsulant define a specific embodiment of the wafer-level imager assembly 550. The encapsulant 260 and the semiconductor substrate 110 are then cut along lines S-S to singulate individual microelectronic imagers 10 from each other. FIG. 5E illustrates a singulated microelectronic imager 10 having the same, or at least similar, components as described above with reference to FIG. 1. The encapsulant 260 of the singulated microelectronic imager 10 forms a 5-sided protective casing around the perimeter sides of the stacked lens assembly 200 and the perimeter portion of the top surface along the top spacer 250.

Several embodiments of wafer-level imager assemblies can comprise an imager substrate, such as the substrate 110, and a plurality of imager dies in which the individual imager dies have an image sensor and a plurality of through-substrate interconnects electrically coupled to the image sensor. The wafer-level imager assembly further includes a plurality of stacked lens assemblies, such as the stacked lens assemblies 200, attached to the imager substrate at corresponding imager dies such that the stacked lens assemblies are spaced apart from each other by gaps. The individual stacked lens assemblies have a first lens unit, a base spacer between the first lens unit and the imager substrate, a second lens unit, and an intermediate spacer between the first lens unit and the second lens unit. The wafer-level imager assembly further comprises an encapsulant disposed in the gaps between the stacked lens assemblies. The base spacer, the first optics element, the intermediate spacer, and the second optics element can optionally have a common coefficient of thermal expansion. Additionally, the common coefficient of thermal expansion of the stacked lens assembly components can be at least approximately the same as that of the imager substrate, and the stacked lens assemblies can optionally include a top spacer bonded to the second lens unit.

Additional embodiments are directed to individually packaged integrated imagers that comprise an imager die, such as one of the imager dies 100 with a semiconductor substrate, an image sensor configured to sense radiation at a first side of the substrate, and a plurality of interconnects electrically coupled to the image sensor and extending to a second side of a substrate. The packaged integrated imagers can further include a stacked lens assembly, such as one of the stacked lens assemblies 200, attached to the imager die. The stacked lens assembly comprises a first lens, a base spacer separating the first lens from the semiconductor substrate, a second lens aligned with the first lens, and an intermediate spacer between the first and second lenses. The first lens, the second lens, the base spacer and the intermediate spacer can have components with a common coefficient of thermal expansion, which can be at least approximately equal to that of the semiconductor substrate of the imager die.

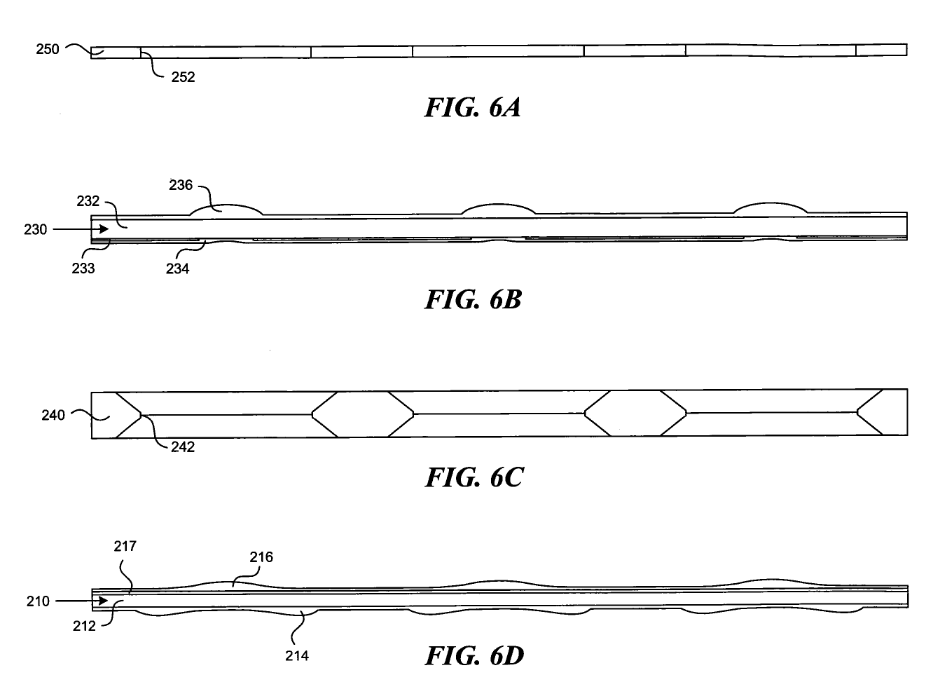

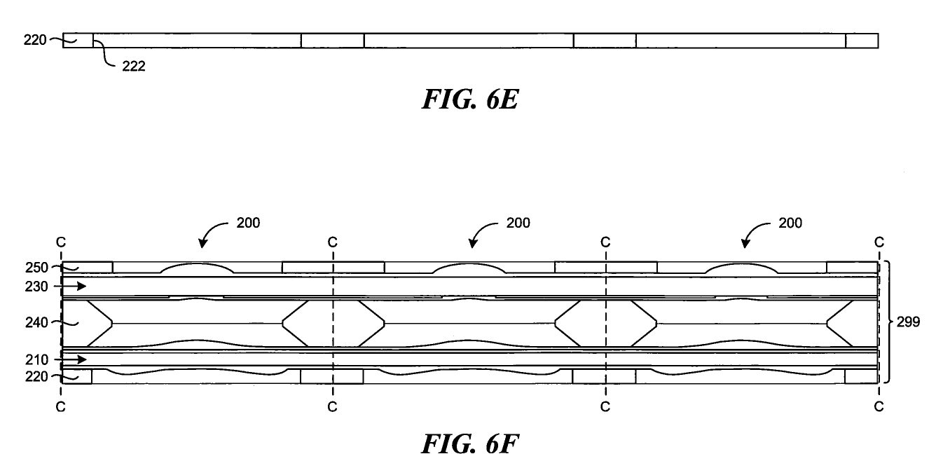

FIGS. 6A-6F illustrate another embodiment of a method for forming a wafer-level stacked lens assembly. FIG. 6A illustrates an early stage that includes providing the top spacer substrate 250. The top spacer substrate 250, for example, can be a silica glass or quartz wafer having a plurality of openings 252 arranged in a lens pattern. FIG. 6B illustrates a subsequent stage including providing the second lens unit 230. This stage of the process can include depositing and patterning the aperture layer 233 on one side of the second substrate 232, imprinting or etching the first lens elements 234 at the apertures of the aperture layer 233, and imprinting or etching the second lens elements 236 on the other side of the second substrate 232. FIG. 6E illustrates another stage including providing the intermediate spacer 240 with a plurality of openings 242 etched or otherwise formed in the lens pattern. FIG. 6D illustrates another stage including providing the first lens unit 210 with the first substrate 212 and the first and second lens elements 214 and 216. FIG. 6E illustrates a subsequent stage including providing a base spacer 220 having a plurality of openings 222 arranged according to the lens pattern of the first lens unit 210. FIG. 6F illustrates a subsequent stage in which the wafer-level stacked lens assembly 299 is formed by stacking and bonding together the base spacer 220, the first lens unit 210, the intermediate spacer 240, the second lens unit 230, and the top spacer 250 in the order illustrated in FIG. 6F.

Several embodiments of the methods illustrated in FIGS. 2A-6F accordingly provide methods for manufacturing stacked lens assemblies for integrated imagers comprising attaching a first lens substrate to a base substrate, fixing an intermediate substrate to the first lens substrate, and mounting a second lens substrate to the intermediate substrate. In a specific embodiment, the first lens substrate can be a component of a first lens unit 212 and the second lens substrate can be a component of a second lens unit 232. Additionally, the first and second lens units can have one or more lens elements, aperture layers and/or filters on the substrates as described above or in other combinations.

Additional embodiments of methods can be directed toward manufacturing packaged imager assemblies comprising forming a plurality of imager dies on an imager substrate having a first side and a second side. For example, the imager dies can be the imager sensor dies 100 illustrated above that include an image sensor 120 and through substrate interconnects 130 electrically coupled to the image sensors 120. Embodiments of these methods can further include attaching individual stacked lens assemblies to the imager substrate at corresponding imager dies such that the stacked lens assemblies are spaced apart from each other by gaps. In specific embodiments, the individual stacked lens assemblies can comprise the stacked lens assemblies 200 described above that have a first lens unit and a second lens unit spaced apart from the first lens unit. The first and second lens units, for example, can have one or more lens elements attached to or on first and second substrates, respectively. Embodiments of such manufacturing methods can further include disposing an encapsulant in the gaps between the stacked lens assemblies and cutting through the imager substrate and the encapsulant between the stacked lens assemblies such that the encapsulant covers the sidewalls of the stacked lens assemblies.

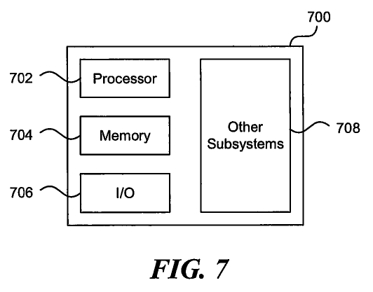

Any one of the semiconductor components described above with reference to FIGS. 1-6F can be incorporated into any of a myriad of larger and/or more complex systems, a representative example of which is system 700 shown schematically in FIG. 7. The system 700 can include a processor 701, a memory 702 (e.g., SRAM, DRAM, flash, and/or other memory device), input/output devices 703, and/or other subsystems or components 704. The foregoing semiconductor components described above with reference to FIGS. 1A-6 may be included in any of the components shown in FIG. 7. The resulting system 700 can perform any of a wide variety of computing, processing, storage, sensing, imaging, and/or other functions. Accordingly, representative systems 700 include, without limitation, computers and/or other data processors, for example, desktop computers, laptop computers, internet appliances, hand-held devices (e.g., palm-top computers, wearable computers, cellular or mobile phones, personal digital assistants, etc), multi-processor systems, processor-based or programmable consumer electronics, network computers, and mini computers. Other representative systems 700 include cameras, light or other radiation sensors, servers and associated server subsystems, display devices, and/or memory devices. In such systems, individual dies can include imager arrays, such as CMOS imagers. Components of the system 700 may be housed in a single unit or distributed over multiple, interconnected units (e.g., through a communications network). The components of the system 700 can accordingly include local and/or remote memory storage devices, and any of a wide variety of computer readable media.

From the foregoing, it will be appreciated that specific embodiments of the invention have been described herein for purposes of illustration, but well-known structures and functions have not been shown or described in detail to avoid unnecessarily obscuring the description of the embodiments of the invention. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Additionally, the term “comprising” is used throughout to mean including at least the recited feature(s) such that any greater number of the same feature and/or additional types of features are not precluded. From the foregoing, it will be appreciated that specific embodiments of the invention have been described herein for purposes of illustration, but that various modifications may be made without deviating from the inventions. For example, many of the elements of one of embodiment can be combined with other embodiments in addition to, or in lieu of, the elements of the other embodiments. Accordingly, the invention is not limited except as by the appended claims.

I/We claim:

1. A wafer level imager assembly, comprising:
an imager substrate including a plurality of imager dies, wherein individual imager dies have an image sensor and a plurality of through substrate interconnects electrically coupled to the image sensor;
a plurality of stacked lens assemblies attached to the imager substrate over corresponding imager dies such that the stacked lens assemblies are spaced apart from each other by gaps, wherein individual stacked lens assemblies have a first lens unit including a first substrate, a base spacer between the first lens unit and the imager substrate, a second lens unit including a second substrate, and an intermediate spacer between the first lens unit and the second lens unit; and
an encapsulant disposed in the gaps between the stacked lens assemblies.

2. The wafer level imager assembly of claim 1 wherein the base spacer, the first substrate, the intermediate spacer, and the second substrate have a common coefficient of thermal expansion.

3. The wafer level imager assembly of claim 1 wherein:
the base spacer comprises glass and has an opening;
the first substrate comprises glass;
the first lens unit further comprises a first lens element on the first substrate;
the intermediate spacer comprises glass and has an aperture;
the second substrate comprises glass; and
the second lens unit further comprises a second lens element on the second substrate.

4. The wafer lever imager assembly of claim 3 wherein the first lens element comprises a first polymeric focal feature and the second lens element comprises a second polymeric focal feature.

5. A packaged integrated imager, comprising:
an imager die having a semiconductor substrate including a first side and a second
side, an image sensor at the first side, and a plurality of interconnects electrically coupled to the image sensor and extending to the second side of the substrate; and
a stacked lens assembly attached to the imager die, the stacked lens assembly comprising a plurality of substrates, lens elements on the substrates, and a plurality of spacers, wherein the substrates and the spacers have common coefficients of thermal expansion.

6. The packaged integrated imager of claim 5 wherein:
the stacked lens assembly comprises a first lens unit including a first substrate and a first lens element;
a base spacer separating the first lens unit from the semiconductor substrate;
a second lens unit including a second substrate and a second lens element; and
an intermediate spacer between the first and second lens units, and wherein the base spacer, the first substrate, the intermediate spacer, and the second substrate comprise glass.

7. The packaged integrated imager of claim 6 wherein the first lens unit further comprises a first focal feature having a first polymeric member on the first glass substrate and the second lens unit further comprises a second focal feature having a second polymeric member on the second glass substrate.

8. The packaged integrated imager of claim 5, further comprising a polymeric encapsulant covering exterior sides of the stacked lens assembly.

9. The packaged integrated imager of claim 8 wherein the polymeric encapsulant comprises a material that is opaque to the radiation sensed by the image sensor.

10. A wafer level stacked lens assembly, comprising:
a base spacer having a plurality of apertures arranged in a lens pattern;
a first lens unit attached to the base spacer, wherein the first lens unit has a first substrate and a plurality of first lenses arranged in the lens pattern;
an intermediate spacer attached to the first lens unit, wherein the intermediate spacer has a plurality of openings arranged in the lens pattern; and
a second lens unit attached to the intermediate spacer, wherein the second lens unit has a second substrate and a plurality of second lenses arranged in the lens pattern, and wherein individual second lenses are aligned with corresponding first lenses.

11. The wafer level stacked lens assembly of claim 10 wherein the base spacer, the first substrate, the intermediate spacer, and the second substrate have approximately the same coefficient of thermal expansion.

12. The wafer level stacked lens assembly of claim 10 wherein the base spacer, the first substrate, the intermediate spacer, and the second substrate comprise glass wafers having a common diameter.

13. The wafer level stacked lens assembly of claim 12 wherein the first lenses comprise first polymer focal features on the first substrate and the second lenses comprise second polymer focal features on the second substrate.

14. The wafer level stacked lens assembly of claim 10, further comprising a top spacer attached to the second lens unit, wherein the top spacer has holes arranged in the lens pattern.

15. A method of manufacturing stacked lens assemblies for integrated imagers, comprising:
attaching a first lens unit having a plurality of first lenses arranged in a lens pattern to a base spacer having a plurality of apertures arranged in the lens pattern such that individual first lenses are aligned with corresponding apertures;
fixing an intermediate spacer having a plurality of openings arranged in the lens pattern to the first lens unit such that individual openings are aligned with corresponding first lenses; and
mounting a second lens unit having a plurality of second lenses arranged in the lens pattern to the intermediate spacer such that individual second lenses are aligned with corresponding openings of the intermediate spacer.

16. The method of claim 15, further comprising:
fabricating the first lens unit by forming first lens elements on one side of a first substrate and forming second lens elements on an opposing side of the first substrate, wherein the first lens elements are aligned with corresponding second lens elements, and wherein the first and second lens elements are formed using an imprint lithography process; and
fabricating the second lens unit by forming first lens elements on one side of a second substrate and forming second lens elements on an opposing side of the second substrate, wherein the first and second lens elements are formed using an imprint lithography process.

17. The method of claim 15, further comprising:
fabricating a portion of the first lens unit by forming first lens elements at one side of a first substrate;
bonding the base spacer to the first lens unit at the one side of the first substrate;
further fabricating the first lens unit after bonding the base spacer to the one side of the first substrate by forming second lens elements at an opposing side of the first substrate;
fabricating a portion of the second lens unit by forming second lens elements at one side of a second substrate;
bonding the intermediate spacer to the one side of the second substrate;
further fabricating the second lens unit after bonding the intermediate substrate to the one side of the second substrate by forming second lens elements at an opposing side of the first substrate; and
bonding the intermediate spacer to the first substrate after forming the second lens elements at the opposing side of the second substrate.

18. The method of claim 17 wherein the base spacer, the first substrate, the intermediate spacer, and the second substrate have a common coefficient of thermal expansion.

19. A method of manufacturing packaged imager assemblies, comprising:
forming a plurality of imager dies on an imager substrate having a first side and a second side, wherein individual imager dies have an image sensor and through substrate interconnects electrically coupled to the imager sensor, and wherein the image sensors are at the first side of the imager substrate and the through substrate interconnects have terminals at the second side of the substrate;
attaching individual stacked lens assemblies to the imager substrate at corresponding imager dies such that the stacked lens assemblies are spaced apart from each other by gaps, wherein individual stacked lens assemblies have a first lens unit and a second lens unit spaced apart from the first lens unit;
disposing an encapsulant in the gaps between the stacked lens assemblies; and
cutting through the imager substrate and the encapsulant between the dies such that encapsulant covers sides walls of the stacked lens assemblies.

20. The method of claim 19 wherein before attaching the individual stacked lens assemblies to the imager substrate, the method comprises providing the individual stacked lens assemblies by:
attaching the first lens unit to a base spacer, wherein the base substrate has a plurality of apertures arranged in a lens pattern and the first lens unit includes a first substrate and a plurality of first lenses arranged in the lens pattern and aligned with corresponding apertures;
fixing an intermediate spacer to the first lens unit, wherein the intermediate spacer includes a plurality of openings arranged in the lens pattern and aligned with corresponding first lenses; and
mounting the second lens unit to the intermediate spacer, wherein the second lens unit includes a second substrate and a plurality of second lenses arranged in the lens pattern and aligned with corresponding openings of the intermediate spacer.

21. The method of claim 20, further comprising:
fabricating the first lens unit by forming first lens elements on one side of the first substrate and forming second lens elements on an opposing side of the first substrate, wherein the first lens elements are aligned with corresponding second lens elements, and wherein the first and second lens elements are formed using an imprint lithography process; and
fabricating the second lens unit by forming first lens elements on one side of the second substrate and forming second lens elements on an opposing side of the second substrate, wherein the first and second lens elements are formed using an imprint lithography process.

22. The method of claim 20, further comprising:
fabricating a portion of the first lens unit by forming first lens elements at one side of the first substrate;
bonding the base spacer to the first lens unit at the one side of the first stratum;
further fabricating the first lens unit after bonding the base spacer to the one side of the first substrate by forming second lens elements at an opposing side of the first substrate;
fabricating a portion of the second lens unit by forming second lens elements at one side of the second substrate;
bonding the intermediate spacer to the one side of the second substrate;
further fabricating the second lens unit after bonding the intermediate substrate to the one side of the second substrate by forming second lens elements at an opposing side of the first substrate; and
bonding the intermediate spacer to the first substrate after forming the second lens elements at the opposing side of the second substrate.

23. The method of claim 20 wherein the base spacer, the first substrate, the intermediate spacer, and the second substrate have a common coefficient of thermal expansion.

24. The method of claim 23 wherein the base spacer, the first substrate, the intermediate spacer, and the second substrate are glass.

25. The method of claim 22 wherein forming the first and second lens elements of the first and second lens units comprises forming polymeric focal elements using imprint lithography processes.
